(19) United States
(12) Patent Application Publication
(10) Pub. No.: US 2018/0040531 A1
(43) Pub. Date: Feb. 8, 2018

(54) METHOD OF MAKING INTERCONNECT SUBSTRATE HAVING ROUTING CIRCUITRY CONNECTED TO POSTS AND TERMINALS

(71) Applicant: BRIDGE SEMICONDUCTOR CORPORATION, Taipei (TW)

(72) Inventors: Charles W. C. Lin, Singapore (SG); Chia-Chung Wang, Hsinchu County (TW)

(21) Appl. No.: 15/785,426

(22) Filed: Oct. 16, 2017

Related U.S. Application Data
(63) Continuation-in-part of application No. 15/642,253, filed on Jul. 5, 2017.
Application No. 15/642,253 is a continuation-in-part of application No. 15/642,256, filed on Jul. 5, 2017.
Application No. 15/642,253 is a continuation-in-part of application No. 14/621,332, filed on Feb. 12, 2015.
Application No. 14/621,332 is a continuation-in-part of application No. 14/846,987, filed on Sep. 7, 2015.
Application No. 14/846,987 is a continuation-in-part of application No. 14/621,332, filed on Feb. 12, 2015.
(60) Provisional application No. 61/949,652, filed on Mar. 7, 2014.

(51) Int. Cl. H01L 23/367; H01L 21/48; H01L 23/498; H01L 23/13

(52) U.S. Cl. CPC H01L 23/367; H01L 23/13; H01L 21/486; H01L 21/4871; H01L 23/49838; H01L 23/49827; H01L 24/16

(57) ABSTRACT

A method of making an interconnect substrate includes steps of: providing a base and a plurality of posts projecting from the base, providing a dielectric compound on the base, forming a top routing circuitry on the dielectric compound and electrically coupled to the posts; and selectively removing portions of the base to form a plurality of terminals. The terminals are below the posts and extend laterally from the posts to provide electrical contacts underneath the dielectric compound. The dielectric compound covers sidewalls of the posts and provides a dielectric platform for the top routing circuitry deposited thereon. The top routing circuitry laterally extends on the dielectric compound and is electrically connected to the terminals by the posts.

### CROSS REFERENCE TO RELATED APPLICATIONS

This application is a continuation-in-part of U.S. application Ser. No. 15/642,253 filed Jul. 5, 2017, a continuation-in-part of U.S. application Ser. No. 15/642,256 filed Jul. 5, 2017. The U.S. application Ser. No. 15/642,253 is a continuation-in-part of U.S. application Ser. No. 14/621,332 filed Feb. 12, 2015 and continuation-in-part of U.S. application Ser. No. 14/846,987 filed Sep. 7, 2015. The U.S. application Ser. No. 14/846,987 is a continuation-in-part of U.S. application Ser. No. 14/621,332 filed Feb. 12, 2015. The U.S. application Ser. No. 14/621,332 claims benefit of U.S. Provisional Application Ser. No. 61/949,652 filed Mar. 7, 2014. The entirety of each of said Applications is incorporated herein by reference.

### FIELD OF THE INVENTION

The present invention relates to a method of making an interconnect substrate and, more particularly, to a method of making an interconnect substrate having a routing circuitry connected to posts and terminals.

### DESCRIPTION OF RELATED ART

Semiconductor chip is susceptible to performance degradation at high operating temperatures. Hence, encapsulating a chip in a molding compound without proper heat dissipation can worsen thermal environment and cause immediate failure during operation. QFN (“Quad Flat No-Lead”) packages that allow a chip disposed on a metal paddle of a lead frame aims to resolve this thermal-related deficiency. U.S. Pat. Nos. 7,102,214, 7,723,163, and 7,790,512 and U.S. Patent Application No. 20080174981 disclosed various QFN packages for such purposes. However, as lead frames are typically formed by etching of a metal sheet, they are unable to provide ultra-fine line routing circuitry needed by many high performance devices.

Further, many power module or light emitting diode (LED) applications require a highly thermally conductive, electrically insulative and low CTE (Coefficient of Thermal Expansion) board for signal transmission. U.S. Pat. Nos. 8,895,998 and 7,670,872 disclosed various interconnect structures using ceramics for such purposes. However, as the ceramic material is brittle and tends to crack during handling, making this type of circuit board prohibitively unreliable for practical usage.

### SUMMARY OF THE INVENTION

A primary objective of the present invention is to provide an interconnect substrate having a routing circuitry disposed on a dielectric compound and electrically coupled to a plurality of post/terminal connecting elements. The routing circuitry disposed on the dielectric compound provides horizontal routing to improve electrical characteristics of the semiconductor assembly, whereas the post/terminal connecting elements offer vertical interconnections between two opposite sides of the interconnect substrate.

Another objective of the present invention is to provide an interconnect substrate optionally having a low-CTE and high thermal conductivity isolator incorporated therein so as to resolve the chip/board CTE mismatch problem, thereby improving the mechanical reliability and thermal characteristics of the semiconductor assembly.

In accordance with the foregoing and other objectives, the present invention provides a method of making an interconnect substrate having routing circuitry connected to posts and terminals, the method comprising steps of: providing a metal plate having a base and a plurality of posts, wherein the posts contact and project from a top side of the base; providing a dielectric compound on the top side of the base, wherein the dielectric compound covers sidewalls of the posts and has a top surface substantially coplanar with top sides of the posts; forming a top routing circuitry on the top surface of the dielectric compound and electrically coupled to the posts; and selectively removing portions of the base to form a paddle and a plurality of terminals in contact with the posts, wherein the paddle and the terminals extend laterally from the posts in lateral directions and each have a larger lateral dimension than that of the posts.

In another aspect, the present invention provides a method of making an interconnect substrate having an isolator, the method comprising steps of: providing a metal plate having a base and a plurality of posts, wherein the posts contact and project from a top side of the base, and the base has a through opening that extends from the top side to a bottom side of the base; inserting an isolator into the through opening of the base, with a top surface of the isolator substantially coplanar with top sides of the posts, wherein the isolator includes a thermally conductive and electrically insulating slug; providing a dielectric compound on the top side of the base, wherein the dielectric compound covers sidewalls of the isolator and the posts and has a top surface substantially coplanar with the top sides of the posts and the top surface of the isolator; forming a top routing circuitry on the top surface of the dielectric compound and electrically coupled to the posts; and selectively removing portions of the base to form a plurality of terminals in contact with the posts, wherein the terminals extend laterally from the posts in lateral directions and each have a larger lateral dimension than that of the posts.

Unless specifically indicated or using the term “then” between steps, or steps necessarily occurring in a certain order, the sequence of the above-mentioned steps is not limited to that set forth above and may be changed or reordered according to desired design.

The method of making the interconnect substrate according to the present invention have numerous advantages. For instance, depositing the dielectric compound to the post/base metal plate can provide a platform for high resolution circuitries disposed thereon, thereby enhancing routing capability of the interconnect substrate. Binding the isolator to the post/terminal connecting elements provides a CTE-compensated platform for the attachment of a semiconductor device and also establishes a heat dissipation pathway for spreading out the heat generated by the semiconductor device.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1 and 2 are cross-sectional and top plan views, respectively, of a metal plate in accordance with the first embodiment of the present invention;

FIG. 3 is a cross-sectional view of the structure of FIG. 1 further provided with a dielectric compound in accordance with the first embodiment of the present invention;

FIGS. 4 and 5 are cross-sectional and top plan views, respectively, of the structure of FIG. 3 after removal of a top portion of the dielectric compound in accordance with the first embodiment of the present invention;

FIGS. 6 and 7 are cross-section and top plan views, respectively, of the structure of FIGS. 4 and 5 further provided with a top routing circuitry in accordance with the first embodiment of the present invention;

FIGS. 8 and 9 are cross-section and bottom plan views, respectively, of the structure of FIGS. 6 and 7 further formed with a paddle and terminals to finish the fabrication of an interconnect substrate in accordance with the first embodiment of the present invention;

FIG. 10 is a cross-sectional view of the structure of FIG. 8 further provided with a semiconductor device and a passive component in accordance with the first embodiment of the present invention;

FIG. 11 is a cross-sectional view of the structure of FIG. 8 further provided with a balance layer in accordance with the first embodiment of the present invention;

FIG. 12 is a cross-sectional view of the structure of FIG. 11 further provided with a bottom routing circuitry in accordance with the first embodiment of the present invention;

FIG. 13 is a cross-sectional view of another aspect of the interconnect substrate in accordance with the first embodiment of the present invention;

FIGS. 14 and 15 are cross-sectional and top plan views, respectively, of a metal plate in accordance with the second embodiment of the present invention;

FIGS. 16 and 17 are cross-sectional and top plan views, respectively, of the structure of FIGS. 14 and 15 further provided with an isolator in accordance with the second embodiment of the present invention;

FIGS. 18 and 19 are cross-sectional and top plan views, respectively, of the structure of FIGS. 16 and 17 further provided with a dielectric compound in accordance with the second embodiment of the present invention;

FIGS. 20 and 21 are cross-sectional and top plan views, respectively, of the structure of FIGS. 18 and 19 further provided with a top routing circuitry in accordance with the second embodiment of the present invention;

FIGS. 22 and 23 are cross-section and bottom plan views, respectively, of the structure of FIGS. 20 and 21 further formed with terminals to finish the fabrication of an interconnect substrate in accordance with the second embodiment of the present invention;

FIGS. 24 and 25 are cross-sectional and bottom plan views, respectively, of the structure of FIGS. 22 and 23 further provided with a balance layer in accordance with the second embodiment of the present invention;

FIGS. 26 and 27 are cross-sectional and bottom plan views, respectively, of the structure of FIGS. 24 and 25 further provided with a bottom routing circuitry in accordance with the second embodiment of the present invention;

FIG. 28 is a cross-sectional view of the structure of FIG. 26 further provided with a semiconductor device and a passive component in accordance with the second embodiment of the present invention;

FIG. 29 is a cross-sectional view of another aspect of the interconnect substrate in accordance with the second embodiment of the present invention;

FIG. 30 is a cross-sectional view of the structure of FIG. 29 further provided with a semiconductor device in accordance with the second embodiment of the present invention;

FIG. 31 is a cross-sectional view of an interconnect substrate in accordance with the third embodiment of the present invention;

FIG. 32 is a cross-sectional view of an interconnect substrate in accordance with the fourth embodiment of the present invention;

FIG. 33 is a cross-sectional view of an interconnect substrate in accordance with the fifth embodiment of the present invention; and

FIG. 34 is a cross-sectional view of the structure of FIG. 33 further provided with a bottom routing circuitry and a metal layer in accordance with the fifth embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the following description of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

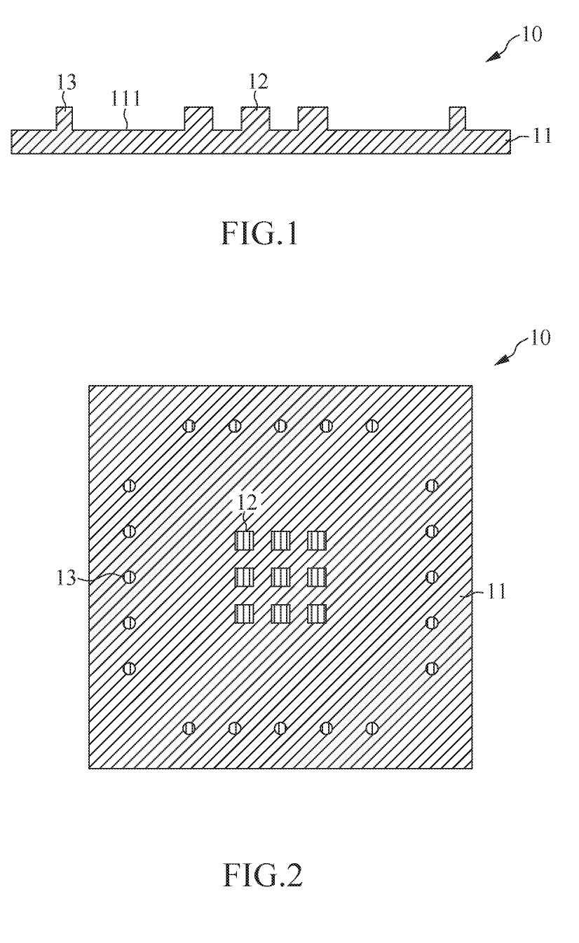

FIGS. 1-9 are schematic views showing a method of making an interconnect substrate that includes a plurality of first posts, a plurality of second posts, a paddle, a plurality of terminals, a dielectric compound and a top routing circuitry in accordance with the first embodiment of the present invention.

FIGS. 1 and 2 are cross-sectional and top plan views, respectively, of a metal plate 10. The metal plate 10 typically is made of copper, aluminum, alloy 42, iron, nickel, silver, gold, combinations thereof, alloys thereof or any other suitable metals. In this embodiment, the metal plate 10 is made of copper and includes a base 11, a plurality of first posts 12 and a plurality of second posts 13. The first posts 12 and the second posts 13 have the same height and contact and project from a top side 111 of the base 11. The base 11 is below the first posts 12 and the second posts 13 and extends laterally from the first posts 12 and the second posts 13 in lateral directions. Preferably, the base 11, the first posts 12 and the second posts 13 are integral with each other. For instance, the metal plate 10 may be a selectively etched single-piece metal or a stamped single-piece metal. By a wet etching or stamping process, the metal plate 10 is shaped to include the base 11, the first posts 12 and the second posts 13. Alternatively, the first posts 12 and the second posts 13 may be deposited on the base 11 by numerous metal deposition techniques, such as electroplating, chemical vapor deposition, physical vapor deposition or others. In this alternative case, there are metallurgical interfaces between the base 11 and the first posts 12 and between the base 11 and the second posts 13, and the first posts 12 and the second posts 13 are in contact with but not integral with the base 11.

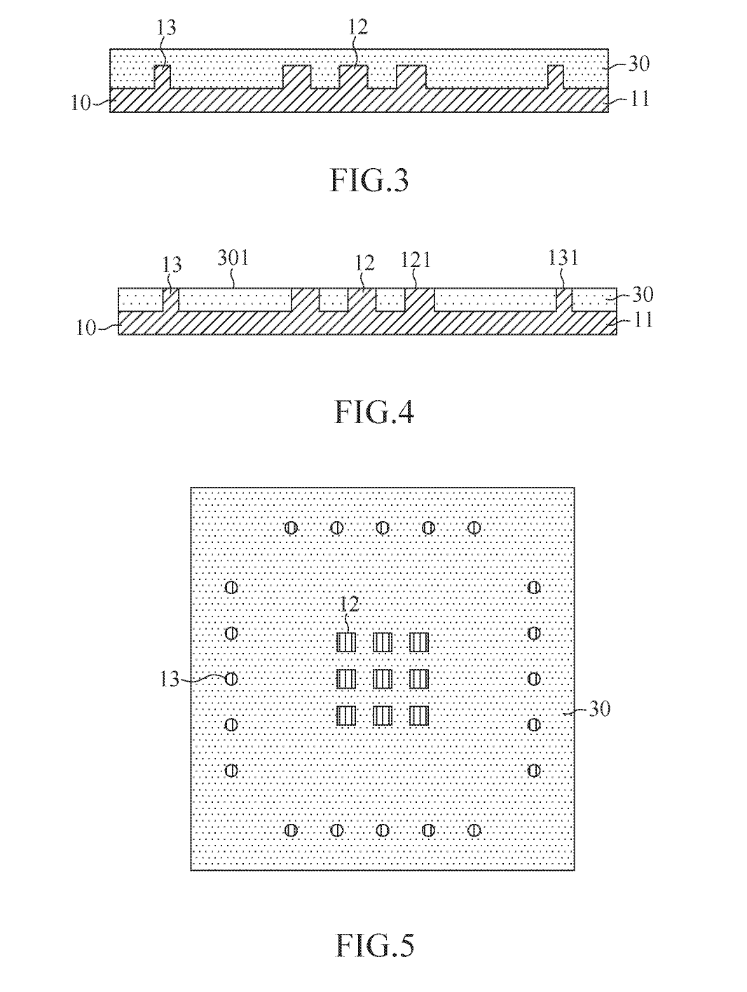

FIG. 3 is a cross-sectional view of the structure provided with a dielectric compound 30. The dielectric compound 30 can be deposited by applying a molding material on the metal plate 10. The molding material can be applied by paste printing, compressive molding, transfer molding, liquid injection molding, spin coating, or other suitable methods. Then, a thermal process (or heat-hardening process) is applied to harden the molding material and to transform it into a solid molding compound. As a result, the dielectric compound 30 covers the base 11, the first posts 12 and the second posts 13 from above and laterally surrounds and conformally coats the first posts 12 and the second posts 13 in lateral directions.

The dielectric compound 30 mainly includes an organic resin binder and particulate inorganic fillers. In this embodiment, the organic resin binder has a coefficient of thermal expansion more than 20 ppm/° C., whereas the particulate inorganic fillers have a coefficient of thermal expansion less than 10 ppm/° C. Further, the content of the particulate inorganic fillers in the dielectric compound 30 preferably ranges from 30 to 90 weight percent based on the total weight of the dielectric compound 30. As a result, the dielectric compound 30 has a coefficient of thermal expansion which is compatible to that of the metal plate 10 so as to prevent cracking or delamination caused by CTE mismatch.

FIGS. 4 and 5 are cross-sectional and top plan views, respectively, of the structure with the first posts 12 and the second posts 13 of the metal plate 10 exposed from above. The upper portion of the dielectric compound 30 can be removed by lapping. By planarization, the dielectric compound 30 has a top surface 301 substantially coplanar with the top sides 121 of the first posts 12 and the top sides 131 of the second posts 13 and has a uniform thickness substantially equal to the height of the first posts 12 and the second posts 13. Further, in order to improve adhesion of a subsequent routing circuitry on the dielectric compound 30, the top surface 301 of the dielectric compound 30 preferably has an arithmetic mean roughness (Ra) in a range of 0.1 to 2 micrometer by roughening.

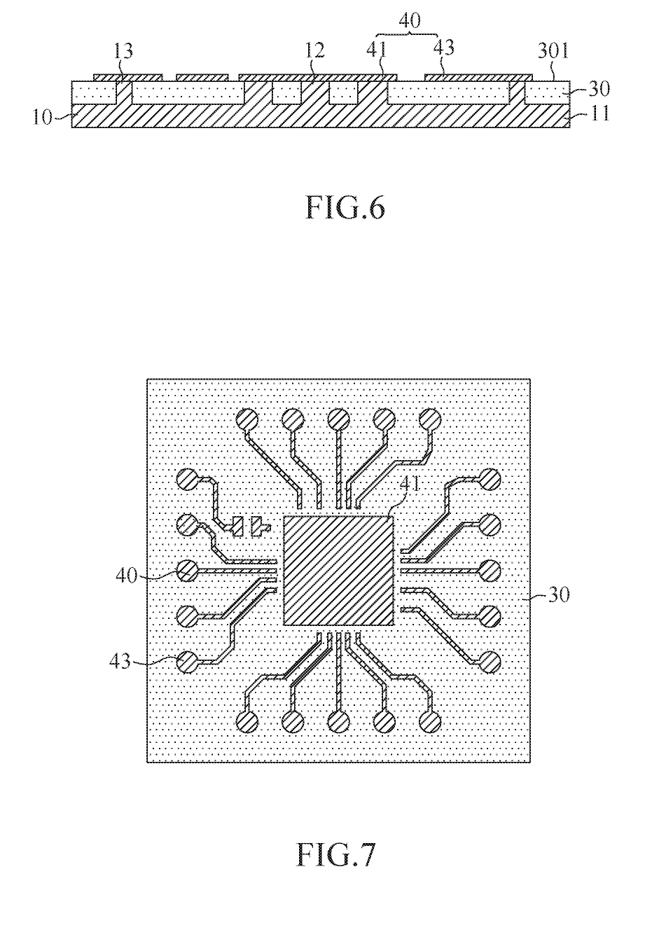

FIGS. 6 and 7 are cross-sectional and top plan views, respectively, of the structure provided with a top routing circuitry 40 on the dielectric compound 30 and electrically coupled to the first posts 12 and the second posts 13. The top routing circuitry 40 is a patterned metal layer and laterally extends on the top surface 301 of the dielectric compound 30 and is thinner than the base 11 of the metal plate 10. The top routing circuitry 40 can be deposited by numerous techniques, such as electroplating, electroless plating, evaporating, sputtering or their combinations. In this embodiment, the top routing circuitry 40 includes a seeding layer in contact with the dielectric compound 30. Specifically, the seeding layer is formed on the topmost surface of the structure prior to the deposition of an electrically conductive layer. The seeding layer may consist of a diffusion barrier layer and a plating bus layer. The diffusion barrier layer is to counterbalance oxidation or corrosion of the electrically conductive layer such as copper. In most cases, the diffusion barrier layer also acts as an adhesion promotion layer to the underlying material and is formed by physical vapor deposition (PVD) such as sputtered Ti or TiW with a thickness in a range from about 0.01 μm to about 0.1 μm. However, the diffusion barrier layer may be made of other materials, such as TaN, or other applicable materials and its thickness range is not limited to the range described above. The plating bus layer is typically made of the same material as the electrically conductive layer with a thickness in a range from about 0.1 μm to about 1 μm. For example, if the electrically conductive layer is copper, the plating bus layer would preferably be a thin film copper formed by physical vapor deposition or electroless plating. However, the plating bus layer may be made of other applicable materials such as silver, gold, chromium, nickel, tungsten, or combinations thereof and its thickness range is not limited to the range described above.

Following the deposition of the seeding layer, an electrically conductive layer (typically a copper layer) is deposited on the seeding layer. The electrically conductive layer can be made of Cu, Ni, Ti, Au, Ag, Al, their combinations, or other suitable electrically conductive material. Once the desired thickness is achieved, the electrically conductive layer as well as the seeding layer can be patterned to form the top routing circuitry 40 by numerous techniques such as wet etching, electro-chemical etching, laser-assist etching, or their combinations, with an etch masks (not shown) thereon that define the top routing circuitry 40. In this embodiment, the top routing circuitry 40 includes a top thermal pad 41 in contact with the first posts 12 to provide a thermal platform for device attachment and top conductive traces 43 electrically coupled to the second posts 13.

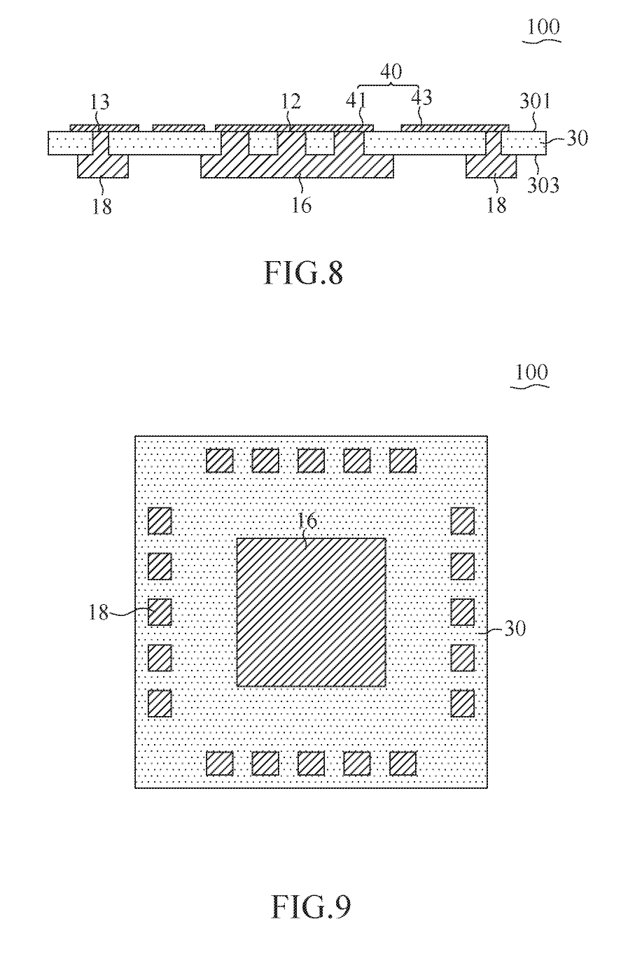

FIGS. 8 and 9 are cross-sectional and bottom plan views, respectively, of the structure formed with a paddle 16 and a plurality of terminals 18. The paddle 16 and the terminals 18 are formed by selectively removing portions of the base 11, and contacts and covers the first posts 12 and the second posts 13 as well as the bottom surface 303 of the dielectric compound 30 from below, respectively. The paddle 16 is located below the first posts 12 and extends laterally from the first posts 12 in lateral directions to have a larger lateral dimension than that of the first posts 12. The terminals 18 are respectively located below the second posts 12 and each of them extends laterally from its corresponding second post 13 in lateral directions to have a larger lateral dimension than that of its corresponding second post 13.

Accordingly, as shown in FIGS. 8 and 9, an interconnect substrate 100 is accomplished and includes a plurality of first posts 12, a plurality of second posts 13, a paddle 16, a plurality of terminals 18, a dielectric compound 30 and a top routing circuitry 40. The first posts 12 and the second posts 13 contact and project from the top sides of the paddle 16 and the terminals 18, respectively. The dielectric compound 30 covers sidewalls of the first posts 12 and the second posts 13 and laterally extends to peripheral edges of the interconnect substrate 100. The top routing circuitry 40 laterally extends on the top surface 301 of the dielectric compound 30 and is thinner than the paddle 16 and the terminals 18, and includes a top thermal pad 41 in contact with the first posts 12 to provide a device attachment pad and top conductive traces 43 in contact with the second posts 13 to provide horizontal routing. The top thermal pad 41 is aligned with and thermally conductible to the paddle 16 through the first posts 12 as heat pipes, whereas the top conductive traces 43 are electrically connected to the terminals 18 through the second posts 13 as vertical routing.

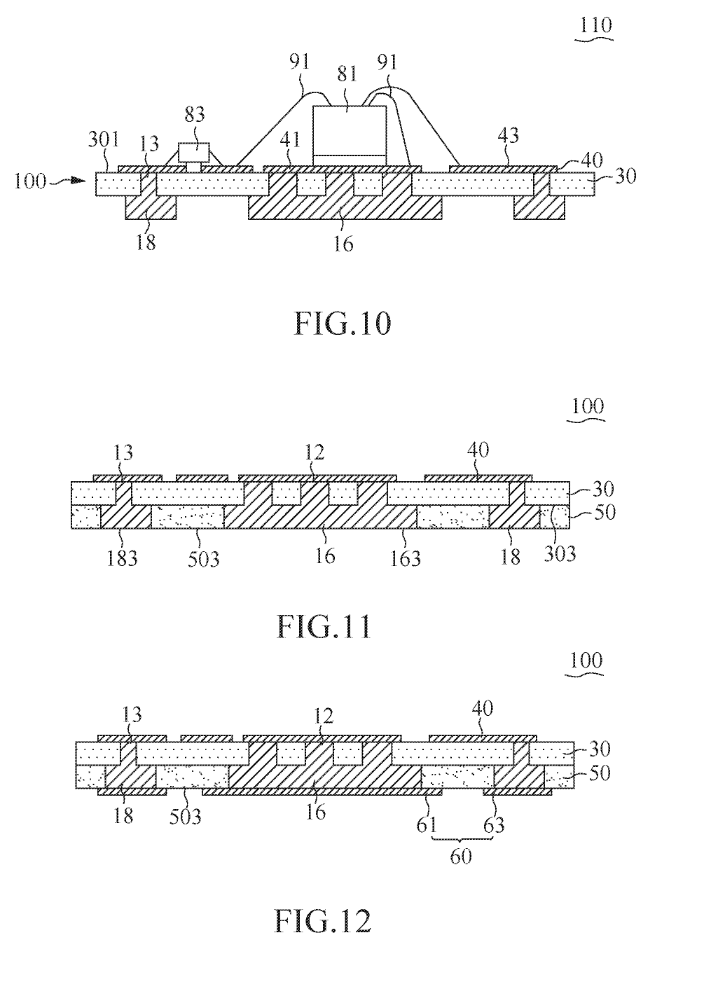

FIG. 10 is a cross-sectional view of a semiconductor assembly 110 with a semiconductor device 81 and a passive component 83 electrically connected to the interconnect substrate 100 illustrated in FIG. 8. The semiconductor device 81, illustrated as a chip, is face-up mounted on the thermal pad 41 and electrically connected to the thermal pad 41 for ground connection and to the conductive traces 43 for signal routing through bonding wires 91. The passive component 83 is mounted over the top surface 301 of the dielectric compound 30 and electrically coupled to the conductive traces 43.

FIG. 11 is a cross-sectional view of the interconnect substrate 100 of FIG. 8 further provided with a balance layer 50. Optionally, the balance layer 50 can be further formed on the bottom surface 303 of the dielectric compound 30 to cover sidewalls of the paddle 16 and the terminals 18 and laterally extend to peripheral edges of the interconnect substrate 100. The balance layer 50 can be deposited by applying a molding material on the dielectric compound 30. Preferably, the balance layer 50 includes an organic resin binder and particulate inorganic fillers with a CTE less than 10 ppm/° C. The content of the particulate inorganic fillers in the balance layer 50 preferably ranges from 30 to 90 weight percent based on the total weight of the balance layer 50. In this embodiment, the balance layer 50 is made of the same material as the dielectric compound 30 and has a uniform thickness substantially equal to that of the paddle 16 and the terminals 18. As a result, the exterior surface 503 of the balance layer 50 is substantially coplanar with the bottom side 163 of the paddle 16 and the bottom sides 183 of the terminals 18.

FIG. 12 is a cross-sectional view of the interconnect substrate 100 of FIG. 11 further provided with a bottom routing circuitry 60. Optionally, the bottom routing circuitry 60 can be further formed on the exterior surface 503 of the balance layer 50 by a sputtering process and then an electrolytic plating process. In order to improve adhesion of the bottom routing circuitry 60 on the balance layer 50, the exterior surface 503 of the balance layer 50 preferably is roughened to have an arithmetic mean roughness (Ra) in a range of 0.1 to 2 micrometer before deposition of the bottom routing circuitry 60, and bottom routing circuitry 60 preferably has a seeding layer in contact with the balance layer 50. The bottom routing circuitry 60 is a patterned metal layer and laterally extends on the exterior surface 503 of the balance layer 50 and is thinner than the paddle 16 and the terminals 18. In this embodiment, the bottom routing circuitry 60 includes a bottom thermal pad 61 in contact with the paddle 16 and bottom contact pads 63 electrically coupled to the terminals 18. As a result, the bottom routing circuitry 60 is thermally conductible to the top routing circuitry 40 through the first posts 12 and the paddle 16 and is electrically connected to the top routing circuitry 40 through the second posts 13 and the terminals 18.

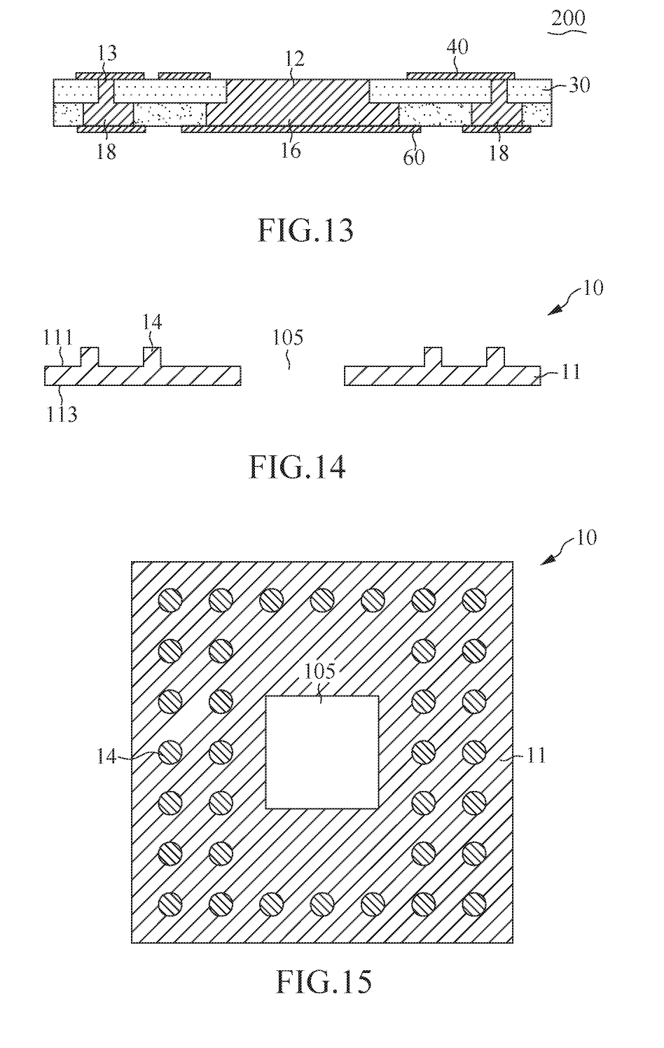

FIG. 13 is a cross-sectional view of another aspect of the interconnect substrate according to the first embodiment of the present invention. The interconnect substrate 200 is similar to that illustrated in FIG. 12, except that (i) the first post 12 has a lager lateral dimension than those illustrated in FIG. 12 and can serve as a thermal platform for device attachment thereon, and (ii) the top routing circuitry 40 and the bottom routing circuitry 60 include no top thermal pad on the first post 12 and no bottom thermal pad underneath the paddle 16, respectively.

### Embodiment 2

FIGS. 14-23 are schematic views showing a method of making an interconnect substrate with an isolator incorporated therein in accordance with the second embodiment of the present invention.

For purposes of brevity, any description in Embodiment 1 above is incorporated herein insofar as the same is applicable, and the same description need not be repeated.

FIGS. 14 and 15 are cross-sectional and top plan views, respectively, of a metal plate 10. The metal plate 10 includes a base 11 and a plurality of posts 14 that contact and project from the top side 111 of the base 11. In this embodiment, the base 11 has a through opening 105 that extends from the top side 111 to the bottom side 113 of the base 11.

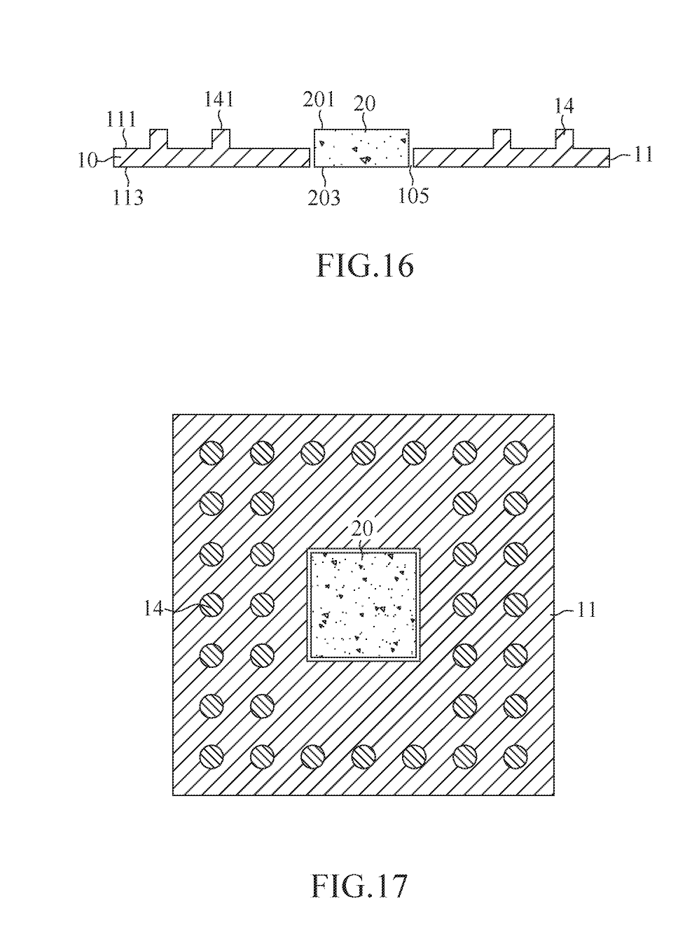

FIGS. 16 and 17 are cross-sectional and top plan views, respectively, of the structure with an isolator 20 inserted into the through opening 105 of the metal plate 10. The isolator 20 is a thermally conductive and electrically insulating slug that typically has high elastic modulus and low coefficient of thermal expansion (for example, 2×10⁻⁶ K⁻¹ to 10×10⁻⁶ K⁻¹), such as ceramic, silicon, glass or others. In this embodiment, the isolator 20 is a ceramic slug having a thickness substantially equal to the combined thickness of the base 11 and the posts 14. The isolator 20 is placed at the through opening 105 of the metal plate 10, with the top sides 141 of the posts 14 substantially coplanar with the top surface 201 of the isolator 20 and the bottom side 113 of the base 11 substantially coplanar with the bottom surface 203 of the isolator 20. As the through opening 105 has a dimension larger than the isolator 20, a gap is left in the through opening 105 between the interior sidewalls of the base 11 and the peripheral edges of the isolator 20. The gap laterally surrounds the isolator 20 and is laterally surrounded by the base 11. In some cases, the interior sidewalls of the base 11 may be used as an alignment guide to ensure the placement accuracy of the isolator 20. Accordingly, the isolator 20 can be accurately confined at a predetermined location, with the peripheral edges of the isolator 20 in close proximity to the interior sidewalls of the through opening 105 of the base 11.

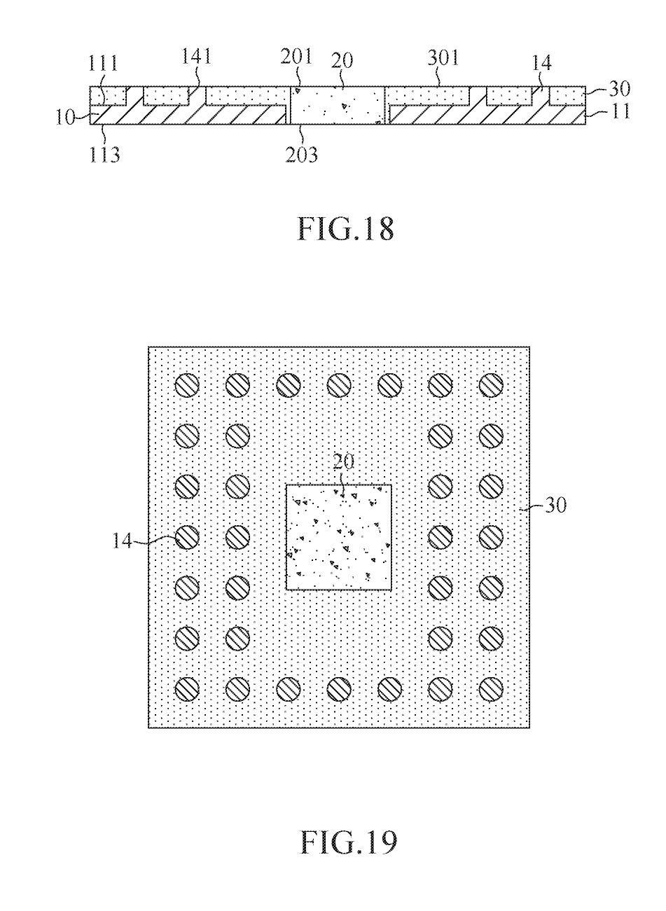

FIGS. 18 and 19 are cross-sectional and top plan views, respectively, of the structure provided with a dielectric compound 30. The dielectric compound 30 covers the top side 111 of the base 11 and sidewalls of the isolator 20 and sidewalls of the posts 14, and has a top surface 301 substantially coplanar with the top sides 141 of the posts 14 and the top surface 201 of the isolator 20. Also, the dielectric compound 30 further fills in the gap between the interior sidewalls of the base 11 and the peripheral edges of the isolator 20. As a result, the dielectric compound 30 provides robust mechanical bonds between the metal plate 10 and the isolator 20.

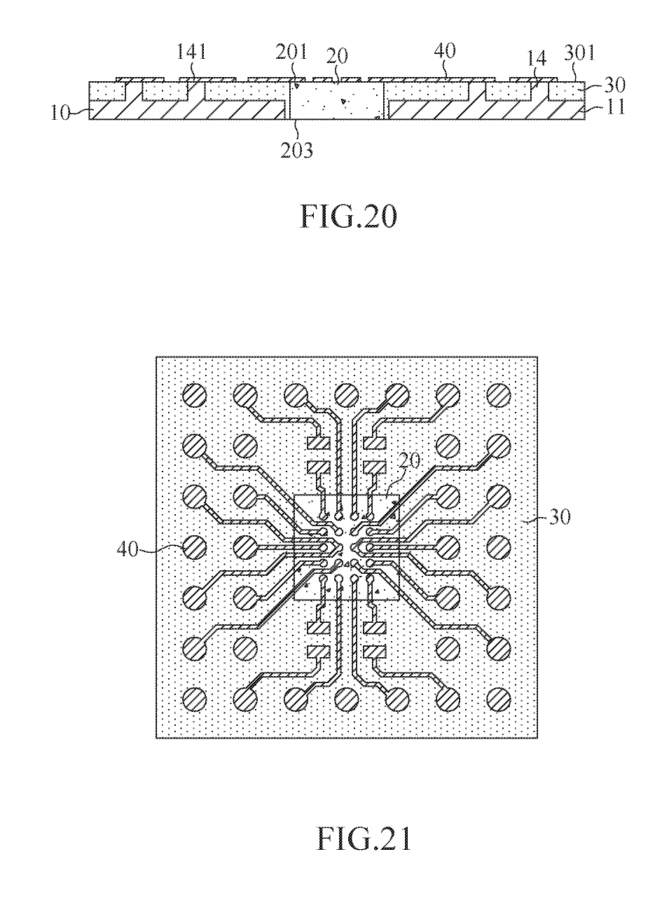

FIGS. 20 and 21 are cross-sectional and top plan views, respectively, of the structure provided with a top routing circuitry 40 by metal pattern deposition. The top routing circuitry 40 laterally extends on the top surface 301 of the dielectric compound 30 and the top surface 201 of the isolator 20, and is electrically coupled to the posts 14.

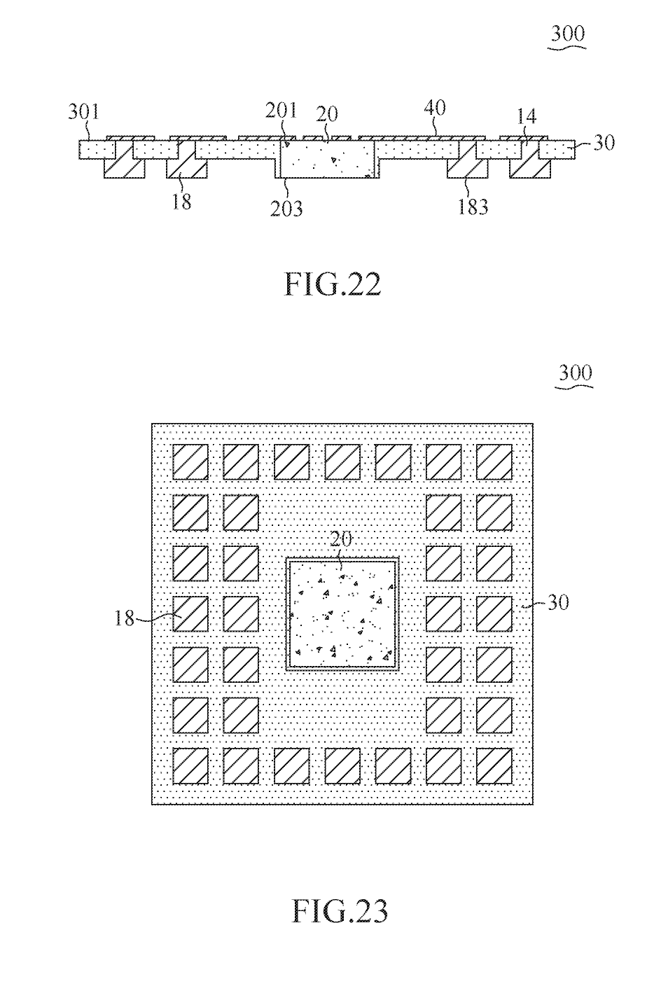

FIGS. 22 and 23 are cross-sectional and bottom plan views, respectively, of the structure formed with terminals 18. The terminals 18 are formed in contact with the posts 14 by selectively removing portions of the base 11, and each of the terminals 18 has a bottom side 183 substantially coplanar with the bottom surface 203 of the isolator 20. As a result, an interconnect substrate 300 is accomplished and includes a plurality of posts 14, a plurality of terminals 18, an isolator 20, a dielectric compound 30 and a top routing circuitry 40. In this embodiment, the top routing circuitry 40 provides electrical contacts on the isolator 20 for device connection and is electrically connected to the terminals 18 by the posts 14.

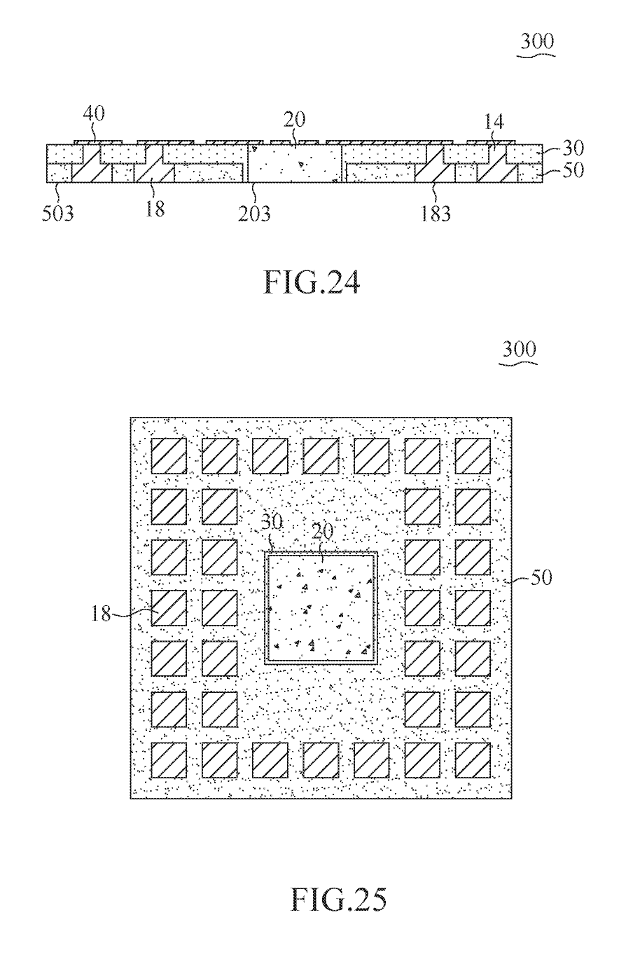

FIGS. 24 and 25 are cross-sectional and bottom plan views, respectively, of the interconnect substrate 300 of FIGS. 22 and 23 further provided with a balance layer 50. Optionally, the balance layer 50 can be further provided to cover sidewalls of the terminals 18 and laterally extend to peripheral edges of the interconnect substrate 300. In this illustration, the exterior surface 503 of the balance layer 50 is substantially coplanar with the bottom sides 183 of the terminals 18 and the bottom surface 203 of the isolator 20.

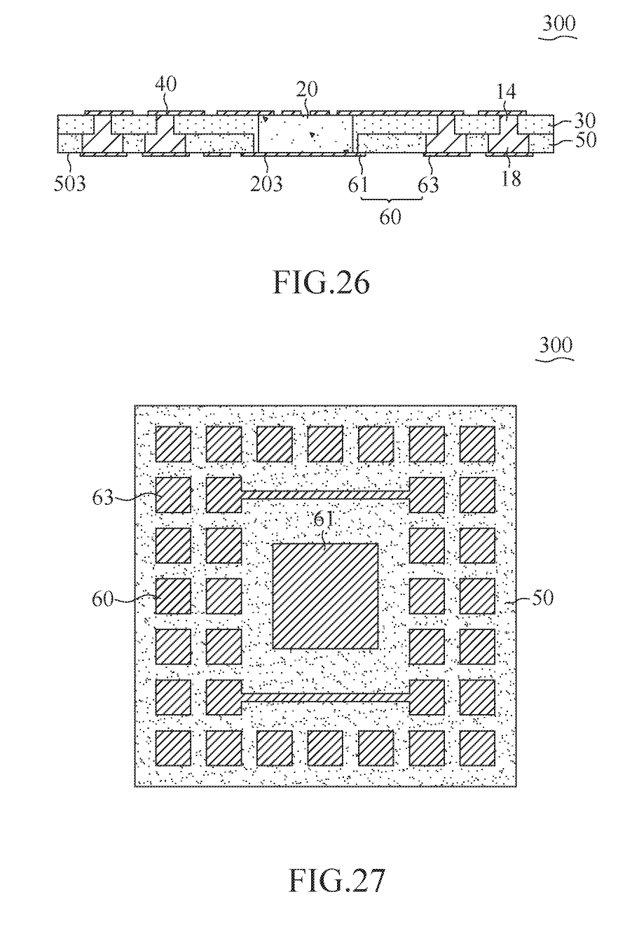

FIGS. 26 and 27 are cross-sectional and bottom plan views, respectively, of the interconnect substrate 300 of FIGS. 24 and 25 further provided with a bottom routing circuitry 60. Optionally, the bottom routing circuitry 60 can be further formed on the bottom surface 203 of the isolator 20 and the exterior surface 503 of the balance layer 50. In this embodiment, the bottom routing circuitry 60 includes a bottom thermal pad 61 in contact with the isolator 20 and bottom contact pads 63 electrically coupled to the terminals 18. As a result, the bottom routing circuitry 60 is thermally conductible to the isolator 20 and is electrically connected to the top routing circuitry 40 through the posts 14 and the terminals 18.

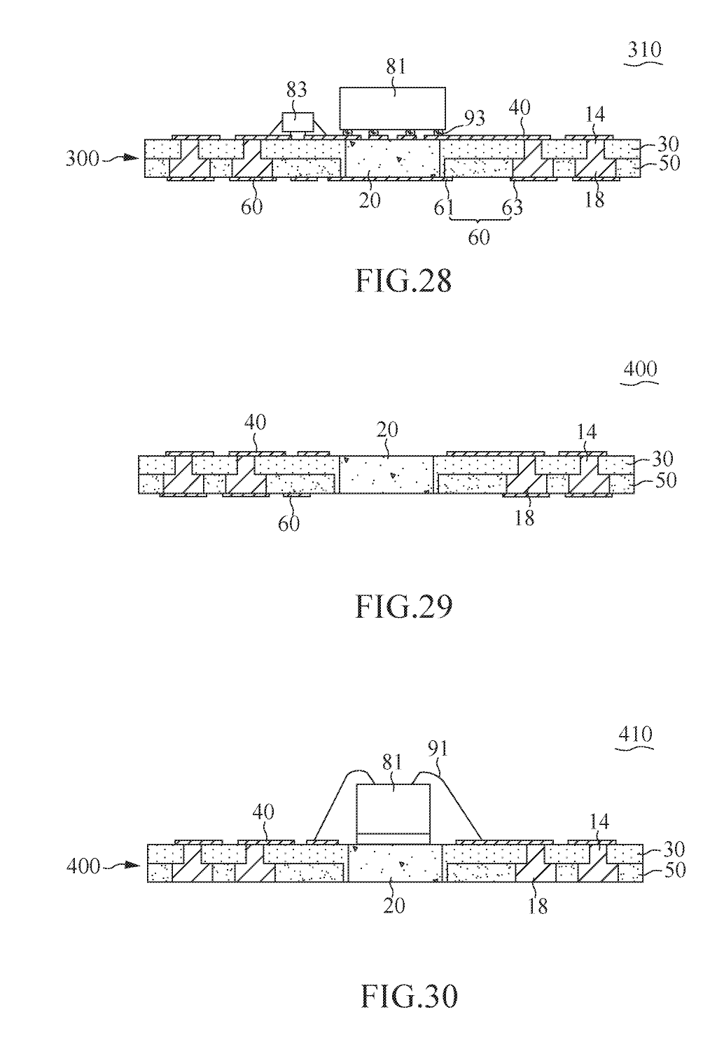

FIG. 28 is a cross-sectional view of a semiconductor assembly 310 with a semiconductor device 81 and a passive component 83 electrically connected to the interconnect substrate 300 illustrated in FIG. 26. The semiconductor device 81 is flip-chip mounted over the isolator 20 and electrically coupled to the top routing circuitry 40 via conductive bumps 93. The passive component 83 is mounted over the dielectric compound 30 and electrically coupled to the top routing circuitry 40.

FIG. 29 is a cross-sectional view of another aspect of the interconnect substrate according to the second embodiment of the present invention. The interconnect substrate 400 is similar to that illustrated in FIG. 26, except that the top routing circuitry 40 does not laterally extend onto the isolator 20 and the bottom routing circuitry 60 include no bottom thermal pad underneath the isolator 20.

FIG. 30 is a cross-sectional view of a semiconductor assembly 410 with a semiconductor device 81 electrically connected to the interconnect substrate 400 illustrated in FIG. 29. The semiconductor device 81 is face-up mounted on the isolator 20 and electrically coupled to the top routing circuitry 40 via bonding wires 91.

### Embodiment

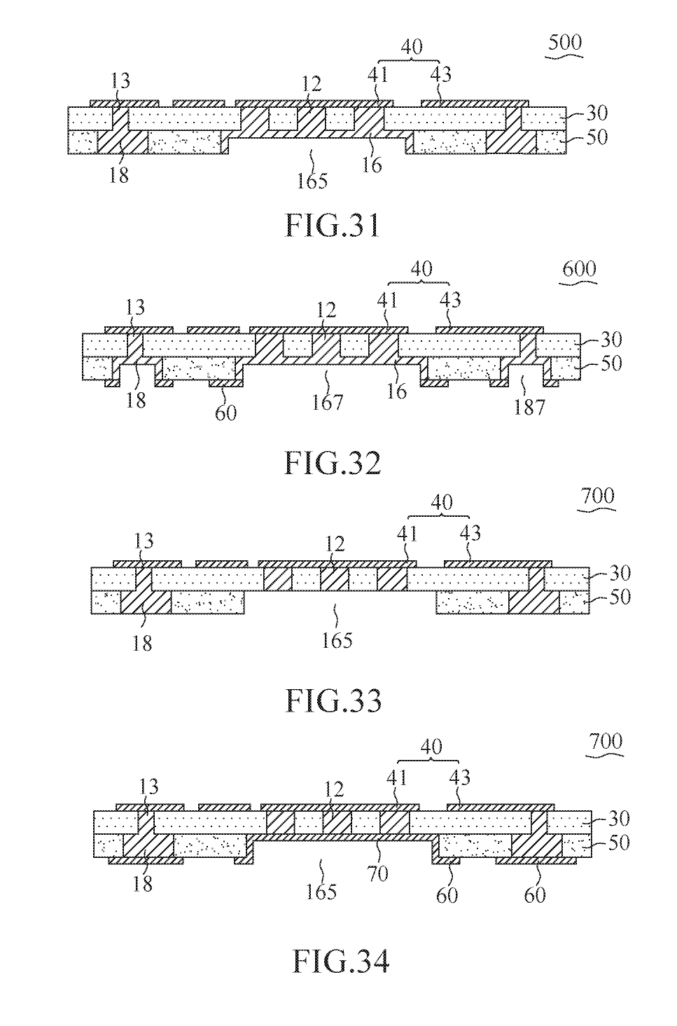

FIG. 31 is a cross-sectional view of an interconnect substrate in accordance with the third embodiment of the present invention.

The interconnect substrate 500 is similar to that illustrated in FIG. 11, except that the paddle 16 is further selectively removed to form a cavity 165 for another device to be disposed therein. In this embodiment, the cavity 165 is surrounded by the remaining metal portion of the paddle 16 and aligned with and thermally conductible to the thermal pad 41 through the first posts 12.

### Embodiment 4

FIG. 32 is a cross-sectional view of an interconnect substrate in accordance with the fourth embodiment of the present invention.

The interconnect substrate 600 is similar to that illustrated in FIG. 12, except that the paddle 16 and the terminals 18 as well as the bottom routing circuitry 60 are further selectively removed to form a first cavity 167 surrounded by the remaining metal portion of the paddle 16 and to form second cavities 187 surrounded by the remaining metal portions of the terminals 18.

### Embodiment 5

FIG. 33 is a cross-sectional view of an interconnect substrate in accordance with the fifth embodiment of the present invention.

The interconnect substrate 700 is similar to that illustrated in FIG. 11, except that the paddle 16 is entirely removed to form a cavity 165 surrounded by the balance layer 50.

FIG. 34 is a cross-sectional view of the interconnect substrate 700 of FIG. 33 further provided with a bottom routing circuitry 60 and a metal layer 70. Optionally, the bottom routing circuitry 60 is deposited on the exterior surface 503 of the balance layer 50, whereas the metal layer 70 covers the sidewalls and the floor of the cavity 165 and is integral with the bottom routing circuitry 60. As a result, the metal layer 70 is thermally conductible to the thermal pad 41 through the first posts 12.

As illustrated in the aforementioned embodiments, a distinctive interconnect substrate is configured to exhibit improved reliability and have a dielectric compound bonded with a plurality of post/terminal connecting elements and a top routing circuitry. The interconnect substrate mainly includes a plurality of posts, a plurality of terminals, a dielectric compound, and a top routing circuitry. In a preferred embodiment, the terminals are located below the posts and the dielectric compound and patterned from a base that is integral with the posts and extends laterally from the posts in lateral directions to peripheral edges of the dielectric compound; the posts are embedded in the dielectric compound and serve as vertical connecting channels; the dielectric compound provides a planar dielectric platform surrounding the posts for the top routing circuitry deposited thereon; and the top routing circuitry provides electrical contacts on the top surface of the dielectric compound for device connection.

Additionally, the interconnect substrate may further include an isolator incorporated with the post/terminal connecting elements by the dielectric compound. The isolator can provide a platform for device attachment and preferably has top and bottom surfaces not covered by the dielectric compound and substantially coplanar with the top sides of the posts and the bottom sides of the terminals, respectively. Specifically, the isolator includes a thermally conductive and electrically insulating slug that may be made of ceramic, silicon, glass or others and typically has high elastic modulus and low coefficient of thermal expansion (for example, 2×10⁻⁶ K⁻¹ to 10×10⁻⁶ K⁻¹). As a result, the isolator, having CTE matching a semiconductor device to be assembled thereon, provides a CTE-compensated platform for the semiconductor device, and thus internal stresses caused by CTE mismatch can be largely compensated or reduced. Further, the isolator also provides primary heat conduction for the semiconductor device so that the heat generated by the semiconductor device can be conducted away.

The post/terminal connecting elements can be formed by selectively removing portions of a post/base metal plate after bonding the dielectric compound to the post/base metal plate. The post/base metal plate can be a selectively etched single-piece metal or a stamped single-piece metal. Alternatively, the post/base metal plate may be formed by depositing the posts on the top side of the base using metal deposition techniques. Further, the post/base metal plate may be formed with a through opening in the base for isolator disposition. Preferably, the thickness of the isolator is substantially equal to the combined thickness of the posts and the terminals. Additionally, by selective removal of the base, a paddle may be formed on the bottom surface of the dielectric compound and in contact with at least one of the posts to provide a larger thermal dissipation surface area than the post. For instance, in a preferred embodiment, the base is patterned to form a paddle in contact with at least one first post as a heat pipe and terminals in contact with second posts as vertical routing. Accordingly, the posts can provide electrical connection or heat conduction pathway between two opposite sides of the dielectric compound, whereas the terminals can serve as electrical contacts on the bottom surface of the dielectric compound.

The dielectric compound can be a resin-based layer and bonded to the top side of the base and sidewalls of the posts and the optional isolator by paste printing, compressive molding, transfer molding, liquid injection molding, spin coating, or other suitable methods. In the interconnect substrate having no isolator incorporated therein, the dielectric compound preferably has a uniform thickness substantially equal to that of the posts. As for the alternative interconnect substrate having the isolator incorporated therein, the dielectric compound preferably further fills in a gap between the isolator and interior sidewalls of the through opening and has a larger thickness where it contacts the isolator than where it contacts the posts. In any case, the dielectric compound preferably has a planar top surface substantially coplanar with the top sides of all the posts and the top surface of the optional isolator. In a preferred embodiment, for CTE match between the dielectric compound and the post/terminal connecting elements, the dielectric compound preferably includes particulate inorganic fillers of CTE less than 10 ppm/C blended therein. The content of the particulate inorganic fillers in the dielectric compound may range from 30 to 90 weight percent based on the total weight of the dielectric compound. As a result, cracking or delamination due to CTE mismatch can be suppressed. Further, the top surface of the dielectric compound preferably has an arithmetic mean roughness (Ra) in a range of 0.1 to 2 micrometer to improve adhesion of the top routing circuitry on the dielectric compound and prevent peeling of the top routing circuitry from the dielectric compound.

The top routing circuitry can be deposited before or after selective removal of the base, and provides electrical contacts on the top surface of the dielectric compound for device connection. Typically, the top routing circuitry is thinner than the paddle and the terminals, and contacts and is electrically coupled to the top sides of the posts without metallized vias in contact with the posts. Optionally, the top routing circuitry may include a top thermal pad for device attachment. The top thermal pad preferably is aligned with and thermally conductible to the paddle by at least one of the posts. Additionally, for the interconnect substrate having the isolator incorporated therein, the top routing circuitry may further extend onto the top surface of the isolator. As a result, the top routing circuitry can provide electrical contacts on the top surface of the isolator to allow a semiconductor device to be flip-chip attached on the isolator, or provide a top thermal pad on the top surface of the isolator for a semiconductor device face-up mounted thereon. The top routing circuitry can be formed by metal deposition using photolithographic process. Preferably, the top routing circuitry is deposited by a sputtering process and then an electrolytic plating process. In order to promote adhesion between the top routing circuitry and the dielectric compound, the top routing circuitry preferably includes a seeding layer that contains a titanium film, a titanium tungsten film or the like in contact with the top surface of the dielectric compound.

Optionally, a balance layer may be further provided on the bottom surface of the dielectric compound to cover sidewalls of the terminals and the paddle and laterally extend to peripheral edges of the interconnect substrate. In a preferred embodiment, the balance layer has a uniform thickness substantially equal to that of the terminals and an exterior surface substantially coplanar with bottom sides of the terminals. The balance layer can be a resin-based layer and bonded to the bottom surface of the dielectric compound as well as sidewalls of the terminals and the paddle by paste printing, compressive molding, transfer molding, liquid injection molding, spin coating, or other suitable methods. The material of the balance layer may be the same as or different from the dielectric compound. For instance, the balance layer may include particulate inorganic fillers of CTE less than 10 ppm/C blended therein. The content of the particulate inorganic fillers in the balance layer preferably ranges from 30 to 90 weight percent based on the total weight of the balance layer. Further, the exterior surface of the balance layer may have an arithmetic mean roughness (Ra) in a range of 0.1 to 2 micrometer to improve adhesion of an optional bottom routing circuitry on the exterior surface of the balance layer and prevent peeling of the optional bottom routing circuitry from the balance layer. After provision of the balance layer, a cavity can be optionally formed by selectively or entirely removing the paddle and aligned with at least one of the posts.

Further, a bottom routing circuitry can be optionally deposited on the exterior surface of the balance layer and electrically connected to the top routing circuitry on the top surface of the dielectric compound by the posts in the dielectric compound and the terminals in the balance layer. Accordingly, the double routing circuitries can enhance routing flexibility of the interconnect substrate. Typically, the bottom routing circuitry is thinner than the paddle and the terminals, and contacts and is electrically coupled to the bottom sides of the terminals without metallized vias in contact with the terminals. Optionally, the bottom routing circuitry may include a bottom thermal pad in contact with the paddle. Additionally, for the interconnect substrate having the isolator incorporated therein, the bottom routing circuitry may further extend onto the bottom surface of the isolator. As a result, the bottom routing circuitry can provide electrical contacts on the bottom surface of the isolator, or provide a bottom thermal pad on the bottom surface of the isolator. The bottom routing circuitry can be formed by metal deposition using photolithographic process. Preferably, the bottom routing circuitry is deposited by a sputtering process and then an electrolytic plating process. In order to promote adhesion between the bottom routing circuitry and the balance layer, the bottom routing circuitry may include a seeding layer that contains a titanium film, a titanium tungsten film or the like in contact with the exterior surface of the balance layer.

The term “cover” refers to incomplete or complete coverage in a vertical and/or lateral direction. For instance, in a preferred embodiment, the balance layer covers sidewalls of the isolator regardless of whether another element such as the dielectric compound is between the isolator and the balance layer.

The phrases “mounted on” and “attached on” include contact and non-contact with a single or multiple support element(s). For instance, in a preferred embodiment, the semiconductor device is attached on the isolator regardless of whether the semiconductor device is separated from the isolator by the top routing circuitry and conductive bumps.

The phrase “aligned with” refers to relative position between elements regardless of whether elements are spaced from or adjacent to one another or one element is inserted into and extends into the other element. For instance, in a preferred embodiment, the interior sidewalls of the base are laterally aligned with the peripheral edges of the isolator since an imaginary horizontal line intersects the interior sidewalls of the base and the peripheral edges of the isolator, regardless of whether another element is between the interior sidewalls of the base and the peripheral edges of the isolator and is intersected by the line, and regardless of whether another imaginary horizontal line intersects the peripheral edges of the isolator but not the interior sidewalls of the base or intersects the interior sidewalls of the base but not the peripheral edges of the isolator. Likewise, in a preferred embodiment, at least one of the posts is aligned with the bottom of the cavity formed by selectively or completely removing the paddle.

The phrase “in close proximity to” refers to a gap between elements not being wider than the maximum acceptable limit. As known in the art, when the gap between the peripheral edges of the isolator and the interior sidewalls of the base is not narrow enough, the isolator may not be accurately confined at a predetermined location. The maximum acceptable limit for a gap between the peripheral edges of the isolator and the interior sidewalls of the base can be determined depending on how accurately it is desired to dispose the isolator at the predetermined location. Thereby, the description “ the peripheral edges of the isolator in close proximity to the interior sidewalls of the through opening” means that the gap between the peripheral edges of the isolator and the interior sidewalls of the through opening is narrow enough to prevent the location error of the isolator from exceeding the maximum acceptable error limit. For instance, the gaps in between the peripheral edges of the isolator and the interior sidewalls of the through opening may be in a range of about 25 to 100 microns.

The phrases “electrical connection”, “electrically connected” and “electrically coupled” refer to direct and indirect electrical connection. For instance, in a preferred embodiment, the terminals are electrically connected to the top routing circuitry by the posts but are spaced from and do not contact the top routing circuitry.

The interconnect substrate according to the present invention has numerous advantages. The post/terminal connecting elements provide primary horizontal and vertical routing, and the top routing circuitry offers further routing to increase routing flexibility of the interconnect substrate.

The interconnect substrate made by this method is reliable, inexpensive and well-suited for high volume manufacture. The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A method of making an interconnect substrate having routing circuitry connected to posts and terminals, the method comprising steps of:
providing a metal plate having a base and a plurality of posts, wherein the posts contact and project from a top side of the base;
providing a dielectric compound on the top side of the base, wherein the dielectric compound covers sidewalls of the posts and has a top surface substantially coplanar with top sides of the posts;
forming a top routing circuitry on the top surface of the dielectric compound and electrically coupled to the posts; and
selectively removing portions of the base to form a paddle and a plurality of terminals in contact with the posts, wherein the paddle and the terminals extend laterally from the posts in lateral directions and each have a larger lateral dimension than that of the posts.

2. The method of claim 1, wherein the top routing circuitry includes a top thermal pad aligned with and thermally conductible to the paddle via at least one of the posts.

3. The method of claim 1, further comprising a step of forming a balance layer on a bottom surface of the dielectric compound, wherein the balance layer covers sidewalls of the paddle and the terminals and has an exterior surface facing away from the dielectric compound.

4. The method of claim 3, further comprising a step of forming a cavity aligned with at least one of the posts by selectively or entirely removing the paddle.

5. The method of claim 3, further comprising a step of forming a bottom routing circuitry on the exterior surface of the balance layer and electrically coupled to the terminals.

6. A method of making an interconnect substrate having isolator, the method comprising steps of:
providing a metal plate having a base and a plurality of posts, wherein the posts contact and project from a top side of the base, and the base has a through opening that extends from the top side to a bottom side of the base;
inserting an isolator into the through opening of the base, with a top surface of the isolator substantially coplanar with top sides of the posts, wherein the isolator includes a thermally conductive and electrically insulating slug;
providing a dielectric compound on the top side of the base, wherein the dielectric compound covers sidewalls of the isolator and the posts and has a top surface substantially coplanar with the top sides of the posts and the top surface of the isolator;
forming a top routing circuitry on the top surface of the dielectric compound and electrically coupled to the posts; and
selectively removing portions of the base to form a plurality of terminals in contact with the posts, wherein the terminals extend laterally from the posts in lateral directions and each have a larger lateral dimension than that of the posts.

7. The method of claim 6, wherein the top routing circuitry further laterally extends onto the top surface of the isolator.

8. The method of claim 6, further comprising a step of forming a balance layer on a bottom surface of the dielectric compound, wherein the balance layer covers sidewalls of the terminals and has an exterior surface facing away from the dielectric compound.

9. The method of claim 8, further comprising a step of forming a bottom routing circuitry on the exterior surface of the balance layer and electrically coupled to the terminals.

10. The method of claim 9, wherein the bottom routing circuitry further laterally extends onto a bottom surface of the isolator.
